(19) United States
(12) Patent Application Publication
(10) Pub. No.: US 2006/0068521 A1
(43) Pub. Date: Mar. 30, 2006

(54) Method of fabricating microelectronic package using no-flow underfill technology and microelectronic package formed according to the method

(76) Inventors: Song-Hua Shi, Chandler, AZ (US); Yongmei Liu, Gilbert, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/953,649

(22) Filed: Sep. 29, 2004

(51) Int. Cl. H01L 21/48; H01L 21/50; H01L 21/44

(52) U.S. Cl. 438/108

(57) ABSTRACT

A method of fabricating a microelectronic package, a package fabricated according to the method, and a system including the package. The method comprises: providing a substrate and a die each having pre-solder bumps thereon; placing a patterned underfill film onto the substrate, the film having a filler therein, being substantially free of added flux and further defining a pattern of through-holes disposed such that corresponding pre-solder bumps of the substrate are exposed through the through-holes after placing the film; placing the die onto the substrate such that pre-solder bumps on the die contact corresponding pre-solder bumps on the substrate; forming solder joints from pre-solder bumps contacting one another; and after forming solder joints, solidifying the film to form the package.

### FIELD

Embodiments of the present invention relate to underfill technology used in the packaging of microelectronic devices.

### BACKGROUND

The use of underfill material in a joint region between a substrate and a die to minimize thermo-mechanical stresses between the substrate and die is well known. Underfill material is typically used in order to compensate for differences in coefficients of thermal expansion (CTE's) between the substrate and the die. Typically, temperatures necessary to reflow the solder joints together lead to an expansion of each of the die and the substrate. During cooling, different shrinkage amounts of the die and substrate could lead to cracks within the die, especially when a mechanically weak interlayer dielectric (ILD) is used. The ILD of the die usually tends to experience increased thermo-mechanical stresses in the area under the solder joints during die and substrate attach, which stresses lead to increased under bump ILD cracking. Because of the above disadvantages with effecting a direct joinder of die and substrate, as mentioned above, no-flow underfill materials are used to compensate for the differences in CTE of the die and the substrate before the joint, die, and substrate cool down.

Typically, as seen in FIG. 1a, an underfill material 10, such as a no-flow underfill material, is dispensed onto a substrate 12 with pre-solder bumps 14. Thereafter, as shown in FIG. 1b, a die 15 having pre-solder bumps 16 at an underside thereof is joined to the substrate by placing pre-solder bumps 14 in registration with pre-solder bumps 16, and by exposing the thus formed die-substrate combination to a compression force and elevated temperature, for example in a thermal compression bonder, in order to form the solder joints. As suggested by FIG. 1b, die side pre-solder bumps 16 and substrate side pre-solder bumps 14 have to penetrate through the underfill material first before being able to contact each other. Ideally, a large compressive force would be required to squeeze out substantially all of the underfill material present between opposing solder bumps. However, the high compressive forces necessary to accomplish the above could damage the die and substrate pre-solder bumps, and are therefore avoided. After the formation of solder joints as shown in FIG. 1b, the underfill material is typically post-cured under elevated temperatures to a low enough viscosity to allow the underfill material to flow away from the area of the solder joints, as best seen in FIG. 1c, and to evenly distribute between the die and the substrate before it is allowed to cure and solidify into cured underfill material 10′.

Disadvantageously, as shown in FIG. 1c, in a package 22 including a substrate and a die joined to one another, some underfill material tends to be entrapped between die-side and substrate-side bumps during thermal compression bonding and the post-curing process. Entrapped underfill 20 in a solder joint 18 as shown can become a location for crack initiation as a result of bump fatigue cracking in reliability stressing tests. In addition, entrapped underfill material can disadvantageously lead to solder electro-migration issues. Such issues arise as a result of entrapped underfill material reducing the effecting cross-sectional area to be traversed by electrical current moving through the affected solder joint. As a result, current density through the solder joint is increased, resulting in some metal atoms in the joint moving from one location within the joint to another, thus disadvantageously tending to cause voids in the joint and ultimate failure of the joint.

In addition, underfill materials used in prior art processes such as the process shown in FIGS. 1a-1c typically includes an added flux component therein, the function of which is to remove any oxide from pre-solder bumps in order to enable the pre-solder bumps to melt and to be joined to one another. Flux is thus necessary in the packaging process. However, flux tends to impact under bump ILD integrity by causing ILD delamination, possibly as a result of a chemical/mechanical interaction between the flux and the passivation layer covering the ILD.

Thus, providing underfill material containing a flux component in the space between a die and a substrate advantageously significantly reduces thermo-mechanical stresses placed on the package as explained above, and further allow the effective solder joint formation by virtue of the presence of the flux in the underfill material. However, as set forth above, use of such underfill material can lead to underfill entrapment and to the impacting of under bump ILD by the flux present in the underfill material, in this way compromising the mechanical and electrical integrity of the resulting package.

One prior art solution has proposed the use of round pre-solder bumps on the substrate in order to reduce problems associated with entrapped underfill material. However, even in the presence of round pre-solder bumps, disadvantages of the prior art noted above have proven to persist, not to mention new disadvantages caused by other possible process issues.

### BRIEF DESCRIPTION OF THE DRAWINGS

Embodiments of the invention are illustrated by way of example and not by way of limitation in the figures of the accompanying drawings, in which the like references indicate similar elements and in which:

FIGS. 1a-1c depict various stages in the formation of a microelectronic package using a no-flow underfill process according to the prior art;

FIG. 2a depicts a top plan view of an embodiment of a no-flow underfill film according to one embodiment;

FIG. 2b is a side elevational view of the film of FIG. 2a;

FIG. 3a is a view similar to FIG. 2a showing the film of FIG. 2a as having been patterned according to one embodiment;

FIG. 3b is a side elevational view of the patterned film of FIG. 3a;

FIGS. 4a-4d′ depict various stages in the formation of a microelectronic package using an underfill process according to an embodiment;

FIG. 5 is a schematic view of a system including a package fabricated according to embodiments of the present invention.

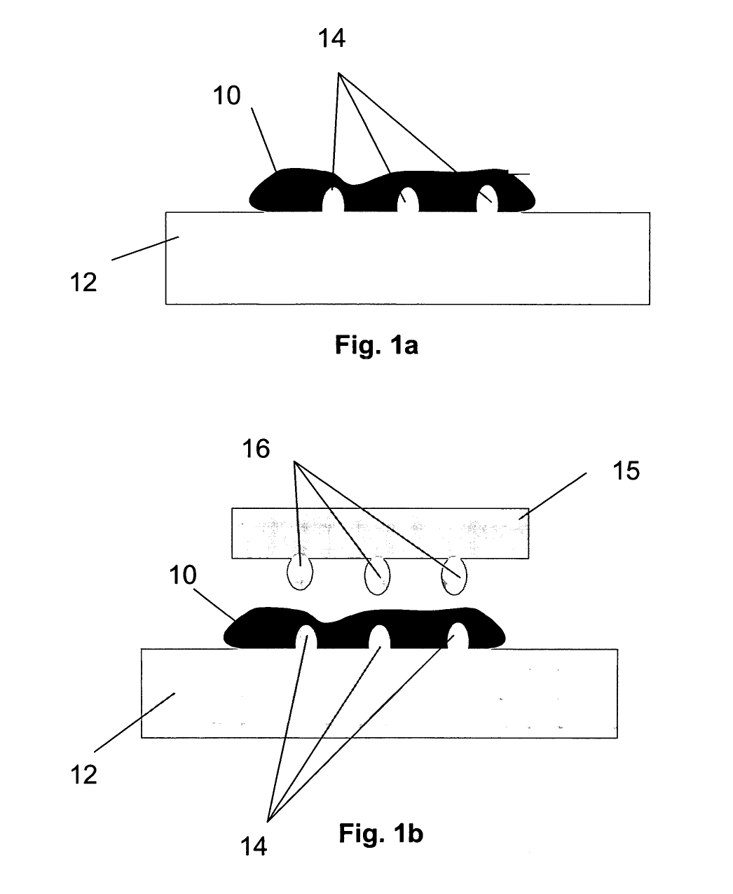

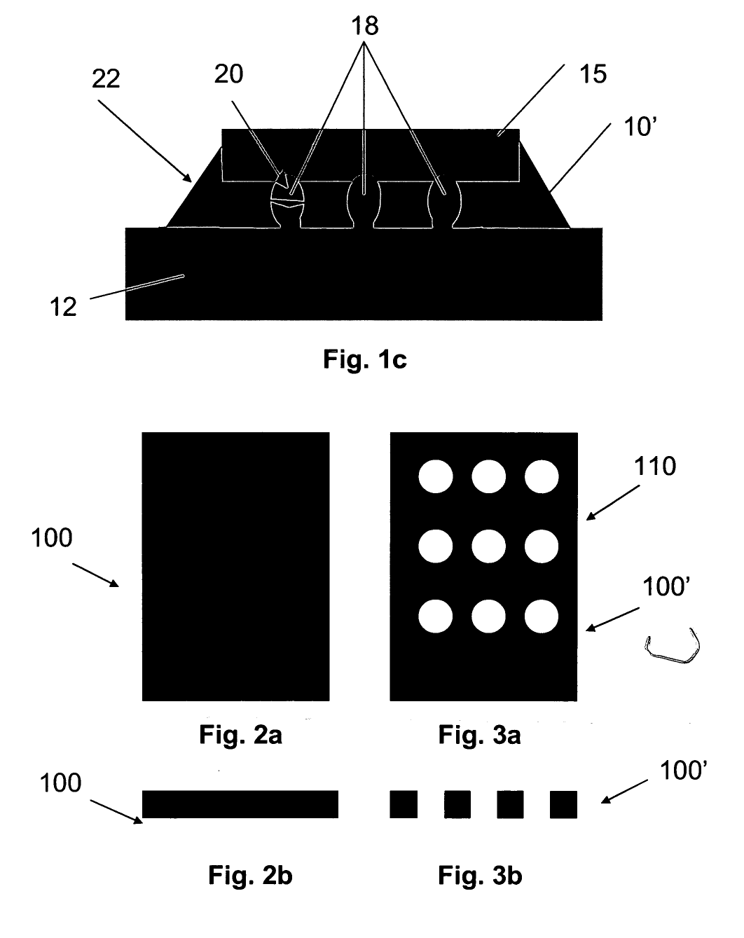

### DETAILED DESCRIPTION

A method of fabricating a microelectronic package, a microelectronic package fabricated according to the method, and a system including the package are disclosed herein.

According to embodiments of the present invention, a method of fabricating a microelectronic package comprises: providing a substrate and a die each having pre-solder bumps thereon; placing a patterned underfill film onto the substrate the film having filler therein, being substantially free of flux and further defining a pattern of through-holes disposed such that corresponding pre-solder bumps of the substrate are exposed through the through-holes after placing the film; providing a flux material having substantially filler free or a filler concentration below about 40% by weight on exposed substrate pre-solder bumps; after providing the flux material, placing the die onto the substrate such that pre-solder bumps on the die directly contact corresponding pre-solder bumps on the substrate; forming solder joints from the bumps contacting one another; and after forming solder joints, solidifying the film and the flux material to form the package.

Methods according to embodiments of the present invention advantageously avoid problems associated with under bump ILD cracking within the die, with underfill entrapment in package solder joints, and further with electro-migration within solder joints, thus resulting in a package with improved mechanical and electrical integrity.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

In addition, the phrase “pre-solder bumps” as used herein refers to electrically conductive bumps that, when joined together through conventional techniques, such as compression and heat treatment, form solder joints.

Referring first to FIGS. 2a-2b, a top plan view and a side-elevational view are depicted of a no-flow underfill film 100. A first stage in the fabrication of a package according to embodiments of the present invention involves the provision of a no-flow underfill film, such as, for example, film 100. Film 100 may be slightly thicker than an interconnect bondline thickness of the package to be formed therewith. The underfill film may be made of a no-flow underfill material, meaning that it is adapted to form a film at relatively low temperatures, such as, for example, at room temperature, for example at about 70 degrees Centigrade, but can flow at relatively low viscosity at elevated temperatures, such as at temperatures above about 100 degrees Centigrade. Underfill film 100 is as yet either not cured, or, partially cured. In particular if the underfill film comprises crystallized resin or relatively high molecular weight resin, the underfill film is not cured, that is, not solidified. On the other hand, if the underfill film includes B-stage epoxy, then it is only partially cured. Examples of possible no-flow underfill films according to embodiments of the present invention include, but are not limited to, B-stage epoxy, solid epoxy such as crystallized epoxy resin, higher molecular weight epoxy (that is, epoxy with a molecular weight above about 5000 g/mol.) and any other suitable resins with no-flow characteristics as noted above, such as cyanate ester resin, PBZ resin, BCB resin, or a mixture thereof. According to embodiments of the present invention, underfill film 100 includes a filler, such as silica, at concentrations between about 40% to about 70% by weight, but contains substantially no added flux component. By “added flux component,” what is meant in the context of the present invention is flux material added to the existing material of the underfill film for the purpose of improving solder bond formation. According to embodiments of the present invention, the material of the underfill film may incidentally include one or more components having fluxing capability as part of the existing chemical composition of the underfill film. Such components may include, by way of example, some epoxy resins and/or epoxy curing agents such as phenolic resin and anhydride with acidic groups. However, in the context of the instant description, those components are not considered “added flux components,” to the extent that they do not fall under the definition set forth above. Should the existing material of the underfill film incidentally contain one or more components having fluxing capability, according to embodiments of the present invention, such component(s) would have a composition that is harmless to the die passivation layer and to the ILD. In particular, such component(s) should have a composition that will substantially avoid impacting under bump ILD integrity such as by causing ILD delamination, possibly as a result of a chemical/mechanical interaction between the flux and the passivation layer covering the ILD. Examples of such harmless components having fluxing capability have already been set forth above as some epoxy resins and/or epoxy curing agents such as phenolic resin and anhydride with acidic groups.

According to one embodiment, film 100 may be designed in such a way that its die side surface region includes a higher amount of a filler, such as silica, and further such that its substrate side surface region includes a lower amount of a filler, such as silica. For example, a die side surface region of film 100 could have a filler concentration of between about 80% to about 85% silica by weight, while the substrate side surface of film 100 could have a filler concentration of between about 50% to about 55% silica by weight. Advantageously, an underfill film having varying filler concentrations across its thickness would allow the underfill film to exhibit, at each of its die side surface and its substrate side surface, a CTE which is closer to the CTE of the surface to which the underfill film is to be bonded after post-curing (die surface or substrate surface) as compared with an underfill film that has a constant filler concentration across its thickness. According to embodiments of the present invention, filler concentrations of the underfill film may present a continuous gradient across the thickness of the film, or they may present a stepwise change across the thickness of the film. Providing an underfill film having varying filler concentrations across its thickness may be achieved in various ways, as would be recognized by a person skilled in the art. By way of example, gravity may be used to pull the filler, such as silica, toward one side of the underfill film during formation of the film. In the alternative, heat may be used in forming the underfill film to allow the filler, such as silica, to precipitate toward one side of the underfill film. According to still another variation, the underfill film 100 may include a plurality of layers each exhibiting a different filler concentration across its thickness, the underfill layers being attached to one another in order to form the underfill film.

Referring next to FIGS. 3a-3b a top plan view and a side-elevational view are depicted of a patterned underfill film 100′. A next stage in the fabrication of a package according to embodiments of the present invention involves the patterning of a no-flow underfill film to yield a patterned underfill film such as, for example, film 100′. A patterning of underfill film 100 according to embodiments of the present invention aims at providing perforations or through-holes 110 in the film corresponding to a package bump layout of the package to be formed by attaching a given substrate to a given die. According to an embodiment, a diameter of the through holes 110 is preferably between about 50 microns to about 120 microns. The package bump layout corresponds to a solder bump pattern provided on a substrate onto which a die is to be attached, and, equally as well, to a solder bump pattern provided on the die to be attached to the substrate, keeping in mind that the solder bump pattern on the substrate and on the die much be able to be placed in registration with one another during attachment. According to an embodiment of the invention, the through-holes 110 may be provided in the semi-cured film 100 by any method known to one skilled in the art, such as, for example, mechanical punching, laser punching, or photolithography. Typically a range for the thickness of film 100′ is from about 0.03 mm to about 0.08 mm.

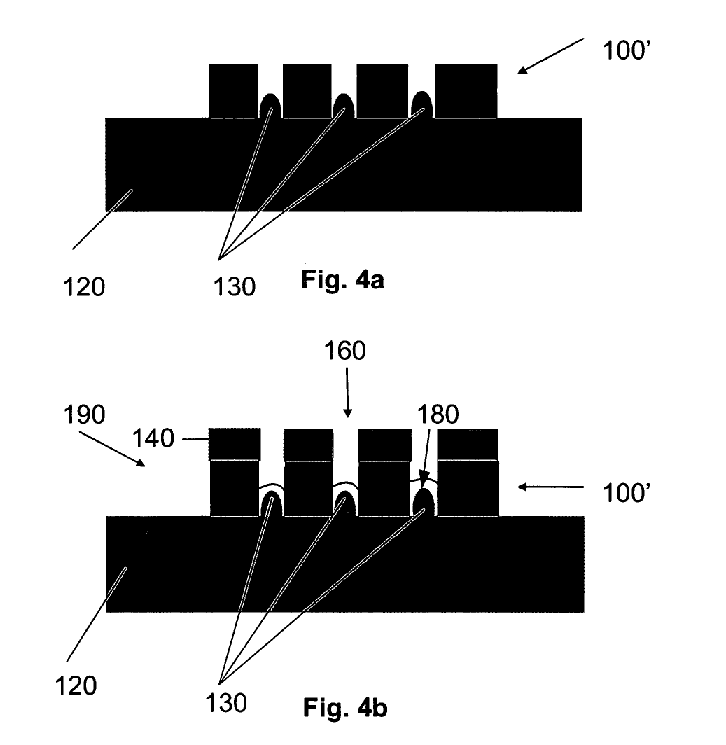

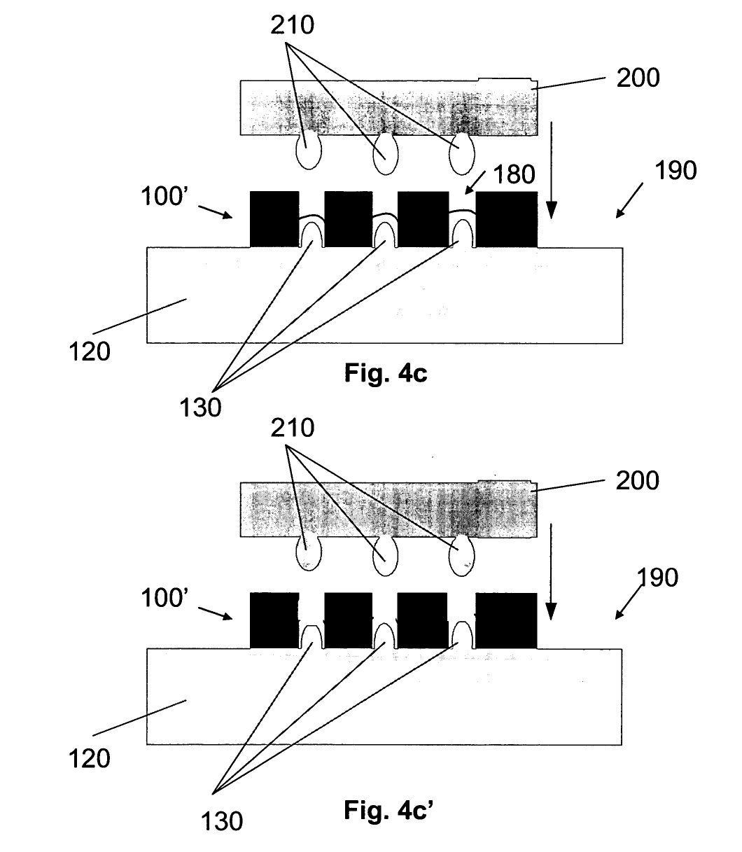

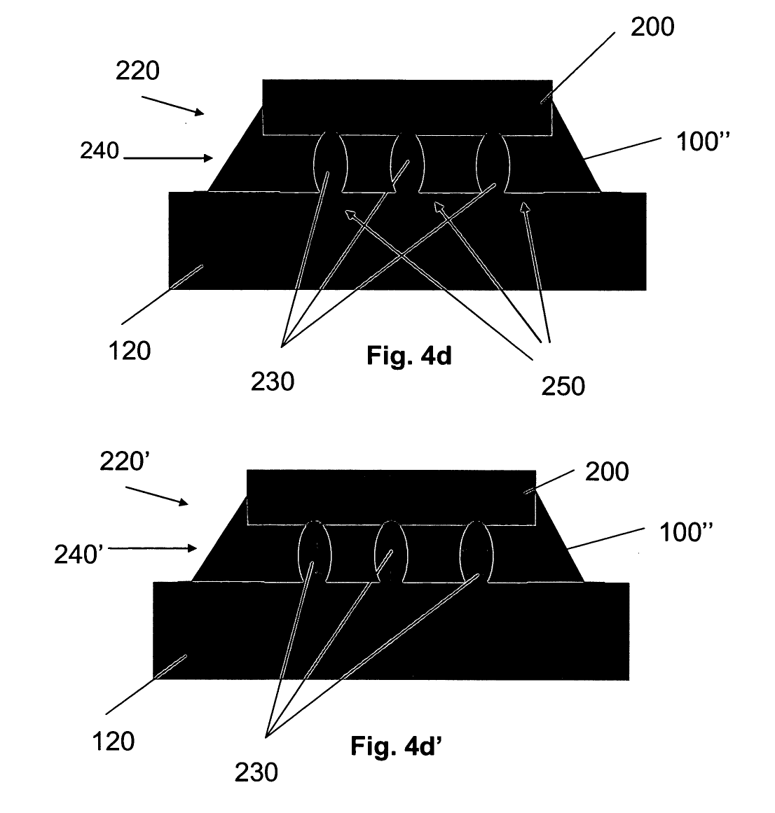

As seen in FIG. 4a, a next stage in the fabrication of a package according to embodiments of the present invention involves placing a patterned underfill film, such as film 100′, on a substrate such that the through-holes are in registration with pre-solder bumps on the substrate. FIGS. 4a depicts film 100′ as having been placed onto a substrate 120 such that through-holes 110 are in registration with pre-solder bumps 130 on the substrate, the film 100′ thus leaving pre-solder bumps 130 exposed.

FIG. 4b depicts a next stage in the fabrication of a package according to one embodiment of the present invention, which involves providing a flux material into the exposed pre-solder bump regions in the through-holes of film 100′. The stage depicted in FIG. 4b would not be necessary should the existing material of the underfill film 100′ incidentally include as part of its chemical composition one or more components with fluxing capability. In such a case, the stage in FIG. 4b would not necessarily need to be followed, to the extent that, as will be explained in further detail below, the one or more components with fluxing capability present in the existing material of the underfill film could play the role of the flux material provided into the exposed pre-solder bump region in the through-holes of film 100′. Thus, according to embodiments of the present invention, providing flux material can take at least two forms. According to one aspect, a flux material distinct from the underfill film if provided in the through holes of film 100′ as seen in FIG. 4b. According to a second aspect, there would be flux material already contained in the existing material of the underfill film 100′, and, in such a case, providing a separate flux material in the through holes of film 100′ could still take place but would not be necessary.

Referring back to FIG. 4b, the provision of a flux material may involve the placing of a mask layer 140 above the semi-cured underfill film 100′, the mask layer 140 having a pattern matching a pattern of film 100′, and the mask further being placed onto the film such that through-holes 160 of the mask are in registration with through holes 110 of film 100′. Thereafter, a flux material 180 may be introduced into the exposed pre-solder bump regions of the substrate through the through holes 160 and 110 as shown. The purpose of the mask layer is to allow an accurate deposition of the flux material into the through holes 110 of film 100′. The flux material may be introduced into the pre-solder bump regions by well known ink-jetting or flux spraying techniques. The flux material may comprise a flux/resin mixture including a flux component and a resin component. According to embodiments of the present invention, the flux component of the flux material may include an organic acid that has at least one carboxylic acid functional group, a mixture of organic acid and alcohol, or a mixture of an organic anhydride and alcohol. The resin component of the flux material may include, by way of example, a silica-free epoxy material with an epoxy curing hardener such as phenolic resin, anhydride, imidazole, and/or an epoxy curing catalyst such as tertiary amine and imidazole. The flux material according to embodiments of the present invention is selected such that it is substantially filler free or has a very low filler concentration (for example, a filler concentration that does not exceed about 40% by weight, and further such that. it exhibits chemical compatibility with the patterned underfill film material. By chemical compatibility, what is meant in the context of embodiments of the present invention is that, after thermal compression bonding and post-curing of the package, the flux material has reacted with underfill film components and formed a polymeric network or solid piece that is bonded to the cured, solid underfill material adjacent thereto. The amount of flux material that is provided in the exposed pre-solder regions on the substrate depends on a number of factors, such as, for example, the chemical nature of the flux and the size of the through holes, and could have a thickness ranging from about 0.5 microns to about 80 microns on the substrate pre-solder bumps. After placing the flux material into the pre-solder bump regions, the mask layer 140 may be removed. It is to be noted that, according to embodiments of the present invention, the mask layer is optional, and would not be needed as a function of the degree of chemical compatibility of the flux material with the underfill film, and on the amount of flux material to be deposited (less flux material diminishing the need for the mask layer).

FIG. 4c depicts a subsequent fabrication stage if the stage shown in FIG. 4b has taken place. If the fabrication stage of FIG. 4b has not been followed, then, the subsequent fabrication stage would correspond to the stage shown in FIG. 4c′, which will be described in further detail below.

According to FIG. 4c, an embodiment of a method according to the present invention includes placing a die 200 having a pre-solder bump region 210 at an underside thereof onto the combination 190 including the substrate 120, pre-solder bumps 130, film 100′, and flux material 180 provided in the exposed pre-solder bump regions of the substrate. The die 200 is placed onto combination 190 such that pre-solder bumps 210 are in registration with pre-solder bumps 130 on the substrate, in this way penetrating the through-holes 110 of film 100′ to contact pre-solder bumps 130. Flux material 180 in through holes 110 advantageously aids in a removal of any oxide present on the surface of pre-solder bumps 130 or 210 as required, enabling the pre-solder bumps to melt together to form a joint during the thermal compression stage in the fabrication of a package according to an embodiment of the present invention, to be described further below. In addition, to the extent that the flux material is substantially silica free, it is not entrapped between die-side and substrate-side pre-solder bumps during the formation of solder joints, thus avoiding the problems associated with entrapped underfill material as occurs in packages of the prior art.

Referring next to FIG. 4c′, as explained above, if the stage in FIG. 4b was not followed, that is, if the existing material of the underfill film 100′ incidentally contains one or more components having fluxing capability such that no additional flux material would need to be provided in the through-holes of underfill film 100′, then, an embodiment of a method according to the present invention would include placing a die 200 having a pre-solder bump region 210 at an underside thereof onto the combination 190 including the substrate 120, pre-solder bumps 130, and film 100′. The die 200 is placed onto combination 190 such that pre-solder bumps 210 are in registration with pre-solder bumps 130 on the substrate, in this way penetrating the through-holes 110 of film 100′ to contact pre-solder bumps 130. The one or more components already present in the material of underfill film 100′ with fluxing capability advantageously aid in a removal of any oxide present on the surface of pre-solder bumps 130 or 210 as required, enabling the pre-solder bumps to melt together to form a joint during the thermal compression stage in the fabrication of a package according to an embodiment of the present invention, to be described further below. In addition, to the extent that the pre-solder bumps are joined through through-holes of the underfill film 100′, the risks of entrapping cured underfill film within solder joints are advantageously minimized.

As seen next in FIG. 4d, a package 220 fabricated according to an embodiment of the present invention is shown, package 220 having been formed including the stages depicted in FIGS. 4b and 4c as described above. Package 220 may correspond to a final stage in the fabrication of a package in the succession for fabrication stages depicted in FIGS. 4a-4c described above. FIG. 4d shows package 220 as including substrate 120 electrically coupled to die 200 through solder joints 230. A solid underfill combination 240 is disposed between the substrate and the die and mechanically connects the substrate and the die to one another. The underfill combination includes a plurality of regions 250 of cured flux material, each of the regions embedding a corresponding one of the solder joints 230, and having a filler concentration below about 50% by weight. The underfill combination also includes a cured underfill material 100″ embedding the plurality of regions 250 of cured flux material, the underfill material having a filler therein and being substantially free of flux.

As seen in FIG. 4d′, a package 220′ fabricated according to an embodiment of the present invention is shown, package 220′ having been formed excluding the stages depicted in FIGS. 4b and 4c as described above. Package 220′ may correspond to a final stage in the fabrication of a package in the succession for fabrication stages depicted in FIGS. 4a and 4c′ described above. FIG. 4d′ shows package 220′ as including substrate 120 electrically coupled to die 200 through solder joints 230. A solid underfill material 240′ is disposed between the substrate and the die and mechanically connects the substrate and the die to one another. The underfill material 240′ includes a cured underfill material 100″ embedding the plurality of solder joints, the underfill material having a filler therein and being substantially free of added flux material, but including one or more components having flux capability. Because of the one or more components in the underfill film 100′, curing film 100′ allows the same to flow to areas around the pre-solder bumps, advantageously allowing the one or more components to facilitate solder joint formation.

Solder joints 230 according to an embodiment of the present invention may be formed by using a thermal compression bonder to melt or reflow the pre-solder bumps in order to join corresponding ones of the pre-solder bumps to one another. During the thermal compression stage, temperatures ranging from about 230 degrees Centigrade to about 240 degrees Centigrade may be applied. Thereafter, solid underfill combination 240 is formed for the embodiment of FIG. 4d by post-curing film 100′ and flux material 180 after formation of the solder joints in order to fully cure and solidify the underfill film and the flux material. For the embodiment of FIG. 4d′, solid underfill material 240′ is formed by post-curing film 100′ containing one or more components with fluxing capability, Post-curing temperatures would range from between about 120 degrees Centigrade to about 180 degrees Centigrade.

Advantageously, using an underfill film without an added flux component results in a reduction in underfill voiding, in an enhancement of die and passivation layer, and in a reduction of low K ILD's cracking by minimizing harmful flux contact with the passivation layer of the die covering the ILD. The absence of added flux from the underfill film results in a reduced tendency of generating voiding during the high temperature thermal compression process, as well as a reduced potential of causing ILD cracking during die and substrate attach. In addition, using a patterned underfill material having through-holes of the pre-solder bump regions of the die and substrate advantageously avoid the problems associated with entrapped underfill, such as, for example, electro-migration. The patterning of the underfill material allows the continued use of the underfill material in packaging, thus preserving the advantages associated with underfill use, such as compensating for CTE differentials between die and substrate, while at the same time substantially eliminating entrapment issues associated with no-flow underfill use. In addition, according to some embodiments of the present invention, isolating added flux use to pre-solder bump regions preserves the advantages of added flux use, such as removing oxides from die-side and substrate-side pre-solder bumps to allow the formation of effective solder joints, while at the same time minimizing flux contact with the passivation layer of the die, in this way substantially eliminating harmful flux effects on the low K ILD of the die as well as eliminating possible underfill and passivation adhesion issues due to the presence of flux residue. In addition, according to embodiments of the present invention, using an added flux material having very low to no filler content further contributes to the avoidance of entrapment of foreign matter within solder joints. Another advantage of embodiments of the present invention is that, to the extent that the underfill film is not present in the area of the pre-solder bumps, the need for its viscosity to be low during thermal compression bonding, such as, for example, a viscosity below that is about equal to the viscosity of a liquid, no longer has importance, to the extent that material of the underfill film will not have to be displaced by the pre-solder bumps during solder joint formation.

It is noted that, although the above description is directed to a method comprising placing the patterned underfill film onto the substrate, embodiments of the present invention also encompass within their scope the fabrication of a package comprising placing the patterned underfill film onto the die first.

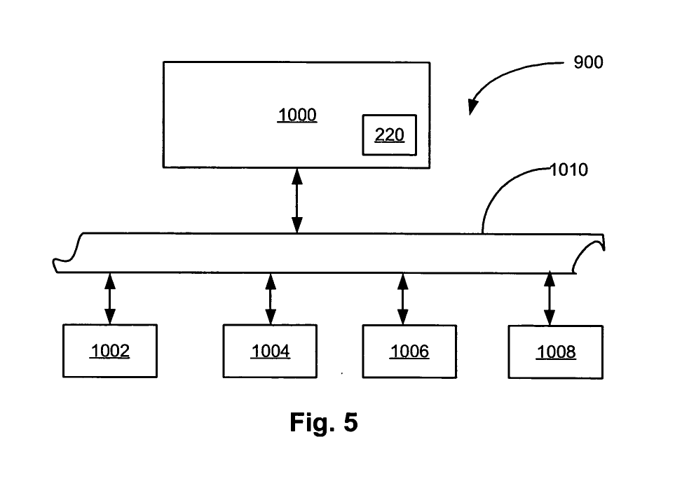

Referring to FIG. 5, there is illustrated one of many possible systems 900 in which embodiments of the present invention may be used. The electronic assembly 1000 including a package 220 similar to package 220 depicted in FIG. 4d. In the alternative, system 900 may include a package 220′ similar to package 220′ depicted in FIG. 4d′. Assembly 1000 may include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 5, the system 900 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 900 may be a wireless mobile phone, a personal digital assistant, a pocket PC, a tablet PC, a notebook PC, a desktop computer, a set-top box, a media-center PC, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method of fabricating a microelectronic package comprising:
providing a substrate and a die each having pre-solder bumps thereon;
placing a patterned underfill film onto the substrate, the film having a filler therein, being substantially free of added flux and further defining a pattern of through-holes disposed such that corresponding pre-solder bumps of the substrate are exposed through the through-holes after placing the film;
placing the die onto the substrate such that pre-solder bumps on the die contact corresponding pre-solder bumps on the substrate;
forming solder joints from pre-solder bumps contacting one another;
after forming solder joints, solidifying the film to form the package.

2. The method of claim 1, further comprising:
providing a flux material having a filler concentration below about 40% by weight on exposed ones of the pre-solder bumps before placing the die onto the substrate; and
solidifying the film and the flux material together to form the package.

3. The method of claim 1, further comprising:
providing an unpatterned underfill film having a filler therein and being substantially free of added flux;
patterning the underfill film with the pattern of through-holes to form the patterned underfill film.

4. The method of claim 3, wherein patterning comprises providing the through-holes using one of mechanical punching, laser punching and photolithography.

5. The method of claim 1, wherein the underfill film comprises a no-flow underfill material.

6. The method of claim 1, wherein the filler comprises silica at a concentration between about 40% to about 70% by weight.

7. The method of claim 1, wherein the film comprises a higher concentration of filler at its die side surface region than at its substrate side surface region.

8. The method of claim 7, wherein the filler is silica, and wherein the die side surface region of the film has a concentration of silica between about 80% to about 85% by weight; and the substrate side surface region of the film has a concentration of silica between about 50% to about 55%.

9. The method of claim 2, wherein the flux material comprises a flux/resin mixture including a flux component and a resin component.

10. The method of claim 9, wherein the flux component comprises one of an organic acid that has at least one carboxylic acid functional group, a mixture of organic acid and alcohol, or a mixture of an organic anhydride and alcohol, and the resin component comprises one of a silica-free epoxy material with an epoxy curing hardener such as phenolic resin, anhydride, imidazole, and/or an epoxy curing catalyst such as tertiary amine and imidazole.

11. The method of claim 2, wherein providing a flux material comprises:
placing a mask layer onto the patterned underfill film after placing the film, the mask layer defining a pattern of through-holes disposed such that through-holes of the film are in registration with corresponding through-holes of the mask layer after placing the mask layer;
providing the flux material on exposed ones of the pre-solder bumps through the mask layer.

12. The method of claim 2, wherein providing the flux material comprises using one of an ink-jetting technique and a spraying technique.

13. The method of claim 2, wherein forming solder joints comprises subjecting a combination comprising the die, the substrate, the patterned underfill film and the flux material to thermal compression bonding.

14. The method of claim 13, wherein subjecting comprises subjecting the combination to a temperature between about 230 degrees Centigrade to about 240 degrees Centigrade.

15. The method of claim 2, wherein solidifying comprises post-curing the film and the flux material at a temperature between about 120 degrees Centigrade to about 180 degrees Centigrade.

16. A microelectronic package comprising:
a substrate;
a die;
a plurality of solder joints disposed between the substrate and the die and electrically connecting the substrate and the die to one another;
a solid underfill combination disposed between the substrate and the die and mechanically connecting the substrate and the die to one another, the underfill combination including:
a plurality of regions of cured flux material, each of the regions embedding a corresponding one of the solder joints and having a filler concentration below about 50% by weight; and
a cured underfill material embedding the plurality of regions of cured flux material, the underfill material having a filler therein and being substantially free of added flux.

17. The package of claim 16, wherein the filler in the underfill material comprises silica at a concentration between about 40% to about 70% by weight.

18. The package of claim 16, wherein the underfill material comprises a higher concentration of filler at its die side surface region than at its substrate side surface region.

19. The package of claim 18, wherein the filler is silica, and die side surface region of the underfill material has a concentration of silica between about 80% to about 85% by weight, and the substrate side surface region of the underfill material has a concentration of silica between about 50% to about 55% by weight.

20. The package of claim 16, wherein the flux material comprises a flux/resin mixture including a flux component and a resin component.

21. The package of claim 20, wherein the flux component comprises one of an organic acid that has at least one carboxylic acid functional group, a mixture of organic acid and alcohol, or a mixture of an organic anhydride and alcohol, and the resin component comprises one of a silica-free epoxy material with an epoxy curing hardener such as phenolic resin, anhydride, imidazole, and/or an epoxy curing catalyst such as tertiary amine and imidazole.

22. A system comprising:
an electronic assembly including a microelectronic package comprising:
a substrate;
a die;
a plurality of solder joints disposed between the substrate and the die and electrically connecting the substrate and the die to one another;
a solid underfill combination disposed between the substrate and the die and mechanically connecting the substrate and the die to one another, the underfill combination including:
a plurality of regions of cured flux material, each of the regions embedding a corresponding one of the solder joints and having a filler concentration below about 40% by weight; and
a cured underfill material embedding the plurality of regions of cured flux material, the underfill material having a filler therein and being substantially free of added flux; and
a graphics processor coupled to the electronic assembly.

23. The package of claim 22, wherein the filler in the underfill material comprises silica at a concentration between about 40% to about 70% by weight.

24. The package of claim 22, wherein the underfill material comprises a higher concentration of filler at its die side surface region than at its substrate side surface region.

25. The package of claim 24, wherein the filler is silica, and die side surface region of the underfill material has a concentration of silica between about 80% to about 85% by weight, and the substrate side surface region of the underfill material has a concentration of silica between about 50% to about 55% by weight.

26. The package of claim 22, wherein the flux material comprises a flux/resin mixture including a flux component and a resin component.

27. The package of claim 26, wherein the flux component comprises one of an organic acid that has at least one carboxylic acid functional group, a mixture of organic acid and alcohol, or a mixture of an organic anhydride and alcohol, and the resin component comprises one of a silica-free epoxy material with an epoxy curing hardener such as phenolic resin, anhydride, imidazole, and/or an epoxy curing catalyst such as tertiary amine and imidazole.
